(19) United States
(12) Patent Application Publication
(10) Pub. No.: US 2020/0006255 A1
(43) Pub. Date: Jan. 2, 2020

(54) SEMICONDUCTOR MODULE

(71) Applicant: Taiyo Yuden Co., Ltd., Tokyo (JP)

(72) Inventors: Takashi NUNOKAWA, Tokyo (JP); Takayuki TAKANO, Tokyo (JP)

(21) Appl. No.: 16/456,448

(22) Filed: Jun. 28, 2019

(30) Foreign Application Priority Data
Jun. 29, 2018 (JP) 2018-124020

(51) Int. Cl. H01L 23/00; H01L 23/367; H01L 23/31; H01L 23/498; H01L 25/18; H01L 25/07

(52) U.S. Cl. CPC H01L 23/564; H01L 2924/3511; H01L 23/3142; H01L 23/49838; H01L 24/32; H01L 25/18; H01L 25/072; H01L 2224/32225; H01L 2924/19105; H01L 2924/19041; H01L 2924/19043; H01L 2924/1203; H01L 2924/10253; H01L 2924/10272; H01L 2924/1033; H01L 2924/13055; H01L 2924/13091; H01L 23/3672

(57) ABSTRACT

A semiconductor module includes: a dielectric film that has a first surface and a second surface opposed to the first surface, the first surface including a first mounting area and a second mounting area; a plurality of circuit parts that includes a first circuit part and a second circuit part, the first circuit part being mounted on the first mounting area, the second circuit part being mounted on the second mounting area; an electrode layer that is disposed on the second surface and includes a plurality of electrode portions to be electrically connected to the plurality of circuit parts; and a sealing layer that includes a first sealing resin portion and a second sealing resin portion and seals the plurality of circuit parts, the first sealing resin portion covering the first mounting area, the second sealing resin portion being formed of a resin material softer than the first sealing resin portion and covering the second mounting area.

### CROSS-REFERENCE TO RELATED APPLICATION

This application claims the benefit of Japanese Application No. 2018-124020, filed Jun. 29, 2018, which is hereby incorporated by reference in its entirety.

### BACKGROUND

The present disclosure relates to a semiconductor module in which a circuit part and an electrode layer are respectively disposed on one surface of a dielectric layer and the other surface.

In recent years, a surface mount integrated power module called POL (Power Over Lay) has been known (see, for example, Japanese Patent Application Laid-open No. 2014-27272). A semiconductor module of this type typically includes a dielectric film such as polyimide, a circuit part such as a power semiconductor device and a passive part mounted on one surface of the dielectric film, an electrode layer disposed on the other surface of the dielectric film, a sealing layer that covers the circuit part, and the like.

In accordance with the semiconductor module, the circuit part is electrically connected to the electrode layer via the dielectric film, and thus, it is possible to realize a power semiconductor module that achieves high integration of parts and shortening of the wiring length and that can be thinner and miniaturized while securing an insulation withstand voltage. Further, the design freedom of the electrode shape is high, and it is possible to form the electrode terminal in the power semiconductor device that controls passage of a large current into an arbitrary shape and size.

Meanwhile, in this type of semiconductor module, since a support substrate that supports circuit parts includes a dielectric film, there is a problem that the dielectric film warps at the time of mounting on an external substrate (motherboard), which impairs the mounting reliability. In order to solve the problem, by forming a sealing layer that covers the circuit parts on the dielectric film, the rigidity of the semiconductor module is improved to suppress a warp of the dielectric film at the time of mounting on the external substrate.

### SUMMARY

However, the device characteristics of predetermined circuit parts such as power semiconductor devices are deteriorated due to cure shrinkage stress of a resin forming the sealing layer, and it is difficult to secure target module characteristics before and after the formation of the sealing layer. Meanwhile, there is a problem that it is difficult to efficiently suppress the warp of the dielectric film if the sealing layer is formed of a soft resin material.

In view of the circumstances as described above, it is desirable to provide a semiconductor module capable of suppressing deterioration of device characteristics while suppressing a warp of a dielectric film.

In accordance with an embodiment of the present disclosure, there is provided a semiconductor module, including: a dielectric film; a plurality of circuit parts; an electrode layer; and a sealing layer.

The dielectric film has a first surface and a second surface opposed to the first surface, the first surface including a first mounting area and a second mounting area.

The plurality of circuit parts includes a first circuit part and a second circuit part, the first circuit part being mounted on the first mounting area, the second circuit part being mounted on the second mounting area;

The electrode layer is disposed on the second surface and includes a plurality of electrode portions to be electrically connected to the plurality of circuit parts.

The sealing layer includes a first sealing resin portion and a second sealing resin portion. The sealing layer seals the plurality of circuit parts. The first sealing resin portion covers the first mounting area. The second sealing resin portion is formed of a resin material softer than the first sealing resin portion and covers the second mounting area.

In the semiconductor module, since the sealing layer includes a first sealing resin portion and a second sealing resin portion, it is possible to suppress deterioration of device characteristics while suppressing a warp of the dielectric film.

The first circuit part may include a passive device, and the second circuit part may include a power semiconductor device.

The semiconductor module may further include a frame member disposed on the first surface. The frame member may include a first opening and a second opening, the first opening dividing the first mounting area and housing the first sealing resin portion, the second opening dividing the second mounting area and housing the second sealing resin portion.

The frame member may be formed of a metal material or a ceramic material.

The first sealing resin portion may include a first portion and a second portion having a rectangular shape, the first portion covering the first mounting area, the second portion dividing the second mounting area and being disposed around the second sealing resin portion.

The first sealing resin portion may be formed of an epoxy resin material, and the second sealing resin portion may be formed of a silicone resin material.

The dielectric film may be formed of polyimide.

In accordance with another embodiment of the present disclosure, there is provided a semiconductor module including: a polyimide film having flexibility; a plurality of circuit parts; an electrode layer; a sealing layer; and a frame member.

The polyimide film has a first surface and a second surface opposed to the first surface.

The plurality of circuit parts is provided on the first surface.

The electrode layer is electrically connected to the plurality of circuit parts via vias provided in the polyimide film, and includes a plurality of electrode portions, the plurality of electrode portions being disposed on the second surface and having a thickness in a range of equivalent to the polyimide film to twice or twice or more the polyimide film.

The sealing layer covers the first surface.

The frame member surrounds the sealing layer on the first surface and is exposed to side surfaces located at four sides of the dielectric film.

Each of the plurality of electrode portions may be provided around a side surface of the polyimide film to have a width of not less than 1 cm and not more than 2 cm, and the frame member may be provided at a position overlapping with the plurality of electrode portions.

The plurality of electrode portions may include a comb-shape electrode that is an electrode of a power transistor, the power transistor being one of the plurality of circuit parts.

As described above, in accordance with the present disclosure, it is possible to suppress deterioration of device characteristics while suppressing a warp of a dielectric film.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a schematic perspective view of semiconductor module according to an embodiment of the present disclosure;

FIG. 2 is a schematic plan view of the semiconductor module;

FIG. 3 is a schematic cross-sectional view taken along the line A-A in FIG. 2;

FIG. 4 is a schematic cross-sectional view taken along the line B-B in FIG. 2;

FIG. 5 is a schematic back view of the semiconductor module;

FIG. 6 is an equivalent circuit diagram of main portions of the semiconductor module;

FIG. 7 is a schematic perspective view of a semiconductor module according to a second embodiment of the present disclosure;

FIG. 8 is a schematic plan view showing a semiconductor module according to a modified example;

FIG. 9 is a side sectional view showing main portions of a semiconductor module according to another modified example; and

FIG. 10 is a side sectional view showing main portions of a semiconductor module according to still another modified example.

### DETAILED DESCRIPTION OF EMBODIMENTS

Hereinafter, embodiments of the present disclosure will be described with reference to the drawings.

### First Embodiment

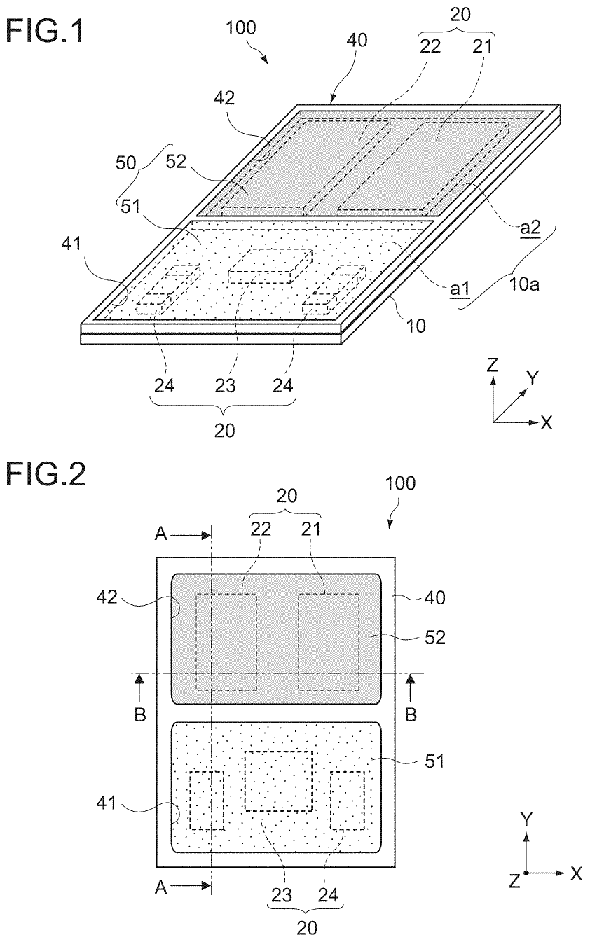

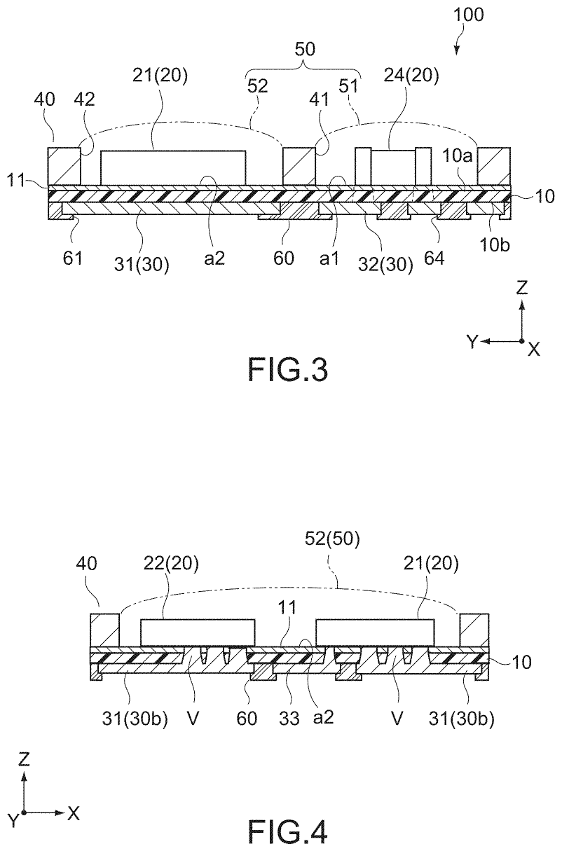

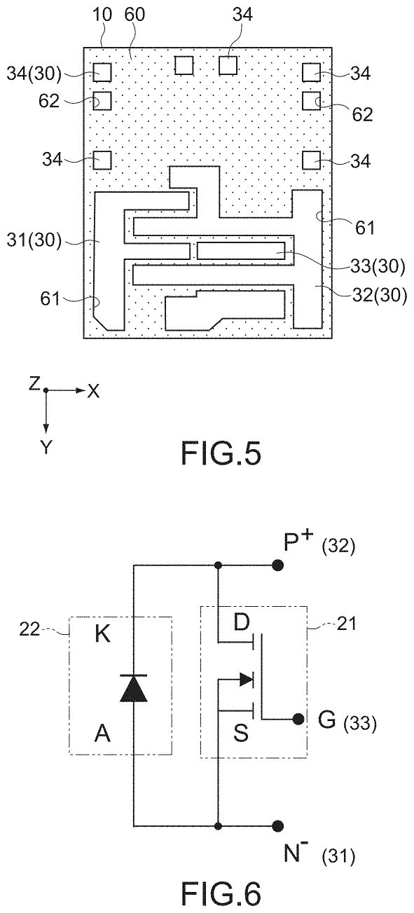

FIG. 1 is a schematic perspective view of a semiconductor module 100 according to an embodiment of the present disclosure. FIG. 2 is a schematic plan view of the semiconductor module 100. FIG. 3 is a schematic cross-sectional view taken along the line A-A in FIG. 2. FIG. 4 is a schematic cross-sectional view taken along the line B-B in FIG. 2. FIG. 5 is a schematic back view of the semiconductor module 100. In each figure, the X axis, Y axis, and Z axis represent three axis directions orthogonal to each other, the X axis and Y axis correspond to the in-plane direction of the semiconductor module 100, and the Z axis corresponds to the thickness direction of the semiconductor module 100.

The semiconductor module 100 includes a dielectric film 10, a plurality of circuit parts 20, an electrode layer 30, a frame member 40, and a sealing layer 50.

[Dielectric Film]

The dielectric film 10 is formed of an electrically insulating resin material having a predetermined thickness. In this embodiment, the dielectric film 10 includes a polyimide film having a thickness of 25 μm. Polyimide is very advantageous from the viewpoints of processability, insulation withstand voltage characteristics, chemical resistance, and the like.

The present disclosure is not limited thereto, and the dielectric film 10 has flexibility. The thickness of the dielectric film 10 can be appropriately set in accordance with the dielectric constant of the material, the magnitude of the insulation withstand voltage, or the like. For example, the thickness of the dielectric film 10 is appropriately selected within the range of not more than 20 μm and not less than 50 μm. The dielectric material is also not limited to polyimide. For example, an appropriate material such as polytetrafluoroethylene (PTFE), polysulfone, and a liquid crystal polymer can be adopted.

The shape of the dielectric film 10 is also not particularly limited, and the dielectric film 10 is typically formed in a rectangular shape. The size of the dielectric film 10 is also not particularly limited. In this embodiment, the dielectric film 10 has a long side parallel to the Y-axis direction of not less than 10 mm and not more than 20 mm and a short side parallel to the X-axis direction of not less than 5 mm and not more than 15 mm.

The dielectric film 10 has a first surface 10a and a second surface 10b opposed to the first surface 10a (see FIG. 3). The first surface 10a is a mount surface on which the plurality of circuit parts 20 are to be mounted, and has a first mount area a1 and a second mount area a2. On the first and second mount areas a1 and a2, the plurality of circuit parts 20 is to be mounted via an adhesive layer 11. The electrode layer 30 to be electrically connected to the plurality of circuit parts 20 is disposed on the second surface 10b via the dielectric film 10 and the adhesive layer 11.

The adhesive layer 11 includes a liquid adhesive or a film-like adhesive sheet applied to the first surface 10a. The type of the adhesive layer 11 is not particularly limited. The adhesive layer 11 is formed of an appropriate insulating resin material such as an epoxy resin material and an acrylic resin material. The thickness of the adhesive layer 11 is not particularly limited, and is, for example, 15 μm. Note that the adhesive layer 11 is formed on the entire area of the dielectric film 10 in this example. The adhesive layer 11 may be partially formed on the dielectric film 10, or may be partially formed below the circuit part 20, for example.

[Circuit Part]

The plurality of circuit parts 20 are mounted on the adhesive layer 11 on the first surface 10a of the dielectric film 10. The plurality of circuit parts 20 typically includes active parts such as semiconductor devices. As the semiconductor devices, an IC part and a discrete part are used. In this embodiment, the semiconductor devices include a power transistor 21 and a diode 22 through which a large current flows. The semiconductor devices further include a control IC 23 that controls the power transistor 21. The circuit parts 20 further include passive parts 24 such as a capacitor and a resistor. A predetermined circuit part among the circuit parts 20 is electrically connected to the electrode layer 30. Note that the circuit parts 20 (21 and 22) are not limited to the combination of the power transistor 21 and the diode 22, and may be two power transistors connected in series like an inverter circuit.

The power transistor 21 includes a BiP transistor, MOSFET, IGBT, or the like formed of Si, or a transistor formed of SiC, GaN, or the like. These semiconductor devices are mounted with the active surface facing the first surface 10a. A heat sink for heat radiation may be bonded to the inactive surface (at the top of the figure) of each of the power transistor 21 and the power diode 22 via a bonding material such as solder and an Ag paste.

Among the plurality of circuit parts 20, the control IC 23 and the passive parts 24, which are first parts, are mounted on the first mount area a1 of the dielectric film 10, and power semiconductor devices such as the power transistor 21 and the power diode 22, which are second parts, are mounted on the second mount area a2 of the dielectric film 10.

[Electrode Layer]

The electrode layer 30 is disposed on the second surface 10b of the dielectric film 10, and typically includes a metal plating layer formed on the second surface 10b. As the metal plating layer, typically, a cupper plating layer is adopted. The electrode layer 30 includes a via V (see FIG. 4) as an interlayer connection portion to be electrically connected to each of the circuit parts 20 via the dielectric film 10.

When forming the electrode layer 30, first, laser light is applied from the side of the second surface 10b to the electrode terminal of each of the circuit parts 20 mounted on the first surface 10a of the dielectric film 10. As a result, the dielectric film 10 and the adhesive layer 11 are drilled, and each electrode terminal is exposed to the side of the second surface 10b. Subsequently, a conductor layer to be a seed layer is formed on the second surface 10b by a sputtering method, and then, a cupper plating layer having a predetermined thickness is formed by an electrolytic plating method. As a result, the electrode layer 30 including the via V is formed.

For the formation of the conductor layer to be a seed layer, the sputtering method does not necessarily need to be adopted, and an electroless plating method may be adopted. The thickness (thickness from the second surface 10b) of the electrode layer 30 is not particularly limited, and is, for example, not less than approximately 20 μm and not more than 50 μm. As a result, the current characteristics of the electrode layer 30 and productivity can be secured.

Since the thickness of the dielectric film 10 is 25 μm as described above, an electrode having a thickness in a range of approximately the same as the thickness of the film to approximately twice the thickness of the film is obtained. The thickness relationship is completely different from that in the print board such as an epoxy board. In the second mount area a2, a polyimide sheet is used because a power switching device is handled. Although a large current flows through the power switching device and it generates high heat generation, driving and heat radiation are made possible by increasing the thickness of the electrode layer 30.

The electrode layer 30 is patterned into a plurality of electrode portions having a predetermined shape by using a photolithographic technology. As shown in FIG. 5, the electrode layer 30 includes a first electrode portion 31 and a second electrode portion 32 that face each other in the X-axis direction and each have a comb shape, a third electrode portion 33 that is disposed between the first and second electrode portions 31 and 32 and long in the X-axis direction, and a plurality of fourth electrode portions 34.

The first electrode portion 31 is connected to a source terminal (S) of the power transistor 21 and an anode terminal (A) of the power diode 22. The second electrode portion 32 is connected to a drain terminal (D) of the power transistor 21 and a cathode terminal (K) of and the power diode 22. The third electrode portion 33 is connected to a gate terminal (G) of the power transistor 21. The fourth electrode portions 34 are connected to respective terminal portions of the control IC 23 and the passive parts 24. FIG. 6 is an equivalent circuit diagram of main portions of the semiconductor module 100.

Note that the circuit shown in FIG. 6 is an example. As another example, also a circuit in which two power transistors are connected in series, which is adopted in an inverter circuit, is conceivable. In this case, reference symbols 21 and 22 each indicate a power transistor. In any case, the second mounting area a2 on which this transistor is mounted is a portion where a large current flows and high heat is generated.

The semiconductor module 100 further includes the solder resist layer 60 (in FIG. 5, the region in which the solder resist layer 60 is formed is shown by dots). The solder resist layer 60 is provided on the second surface 10b of the dielectric film 10, and includes a first opening pattern 61 and a second opening pattern 62. The first opening pattern opens a predetermined region of the electrode layer 30.

The first opening pattern causes the first to third electrode portions 31 to 33 to be partially exposed. The second opening pattern 62 causes the fourth electrode portions 34 to be partially exposed. The regions of the electrode portions 31 to 34 exposed via the first and second opening patterns 61 and 62 are each configured as an external connection terminal to be connected to an external substrate (motherboard) (not shown). Note that in FIG. 5, the area surrounded by the electrodes 34 and 62 exposed in a rectangular shape is a portion where driving control of the transistor provided in the second mounting area a2 is performed, and the conductor pattern of the electrode, wiring, and the like is omitted.

[Sealing Layer]

The sealing layer 50 is provided on the first surface 10a of the dielectric film 10 so as to cover the plurality of circuit parts 20. The sealing layer 50 has a function of improving the rigidity of the dielectric film 10 and inhibiting the outside air containing moisture and the like from coming into contact with the circuit part 20.

The sealing layer 50 includes a first sealing resin portion 51 and a second sealing resin portion 52. The first sealing resin portion 51 covers the first mounting area a1 of the dielectric film 10, and seals the control IC 23 and the passive parts 24. The second sealing resin portion 52 covers the second mounting area a2 of the dielectric film 10, and seals the power transistor 21 and the power diode 22.

The first sealing resin portion 51 is formed of a general-purpose electrically insulating sealing material, typically, an epoxy synthetic resin material. Meanwhile, the second sealing resin portion 52 is formed of an electrically insulating resin material that is softer (having a lower elastic modulus) than the first sealing resin portion 51, e.g., a silicone resin or an epoxy resin having a low stress. Alternatively, in the case of using the frame member 40 described below, for example, a gel-like material having a stress of 0.01 MPa at room temperature or a material having a Tg close to room temperature can be used as the second sealing resin portion 52.

In particular, in the case of GaN, an epoxy resin generally adopted does not achieve desired characteristics due to a stress applied to GaN in some cases. Therefore, the second sealing resin portion 52 is formed of a resin that is softer than the first sealing resin portion 51 or has a lower stress than the first sealing resin portion 51. Although silicone has been shown as an example of the constituent material of the second sealing resin portion 52, another soft or low stress resin is applicable.

[Frame Member]

The frame member 40 is disposed on the first surface 10a of the dielectric film 10. The frame member 40 is bonded to the dielectric film 10 via the adhesive layer 11, similarly to the circuit part 20. The frame member 40 is a rectangular frame including a first opening 41 and a second opening 42, and is formed to have the same shape and size as those of the dielectric film 10 in this embodiment. The first opening 41 divides the first mounting area al, and houses the first sealing resin portion 51. The second opening 42 divides the second mounting area a2, and houses the second sealing resin portion 52.

The material forming the frame member 40 is not particularly limited. A conductor can be used, or a non-conductor can be used. The conductor is typically formed of a metal material. As a result, a heat radiation path of the circuit parts 20 (particularly, power semiconductor devices such as the power transistor 21 and the power diode 22) can be formed. The metal material is not particularly limited, and a material such as copper (Cu) having a high thermal conductivity and a small thermal expansion coefficient is favorable. As the frame member 40, a metal having a high hardness or high melting point such as tungsten (W) and molybdenum (Mo) or an alloy material such as Cu—W and Cu—Mo may be adopted. As a result, it is possible to easily secure desired rigidity. Meanwhile, ceramic materials such as alumina, silica, and boron nitride are favorable as the non-conductor.

The width and height of each frame portion of the frame member 40 are not particularly limited, and are set to appropriate values for achieving such rigidity that can suppress a warp and deformation of the dielectric film 10. The thickness (height) of the frame member 40 may be larger or smaller than the thickness (height) of the circuit part 20.

The first opening 41 and the second opening 42 respectively function as a mold that defines the filling area of the first sealing resin portion 51 and the second sealing resin portion 52. The method of forming the first and second sealing resin portions 51 and 52 is not particularly limited. For example, a printing or potting method can be adopted. The casting may be performed in a reduced pressure atmosphere. As a result, various resins in the molten state can be spread by wetting over the entire area of the first and second openings 41 and 42, and the filling efficiency can be improved. The casted molten resin is cured at a predetermined temperature, and thus, the first and second sealing resin portions 51 and 52 having a shape convex upward are respectively formed in the first and second openings 41 and 42 (see FIG. 4).

[Effect]

In a multi-module device in which a dielectric film is used for a support substrate of parts, a warp is likely to occur in the dielectric film having a small thickness of 25 μm at the time of reflow mounting on an external substrate such as motherboard. Therefore, it is necessary to for a sealing resin on the substrate to make the warp hard to occur. However, in the case where the module is sealed with a resin, semiconductor parts, particularly, the device characteristics of power semiconductor devices formed of a semiconductor material such as Si, GaN, SiC, Ga2O3, and diamond are deteriorated due to cure shrinkage stress of the resin forming the sealing layer, and target module characteristic are not secured in some cases. Meanwhile, in the case where the sealing layer is formed of a soft resin material, there is a problem that it is difficult to effectively suppress the warp of the dielectric film.

In this regard, in the semiconductor module 100 according to this embodiment, the control IC 23 and the passive parts 24 are sealed with the first sealing resin portion 51, and the power semiconductor devices such as the power transistor 21 and the power diode 22 are sealed with the second sealing resin portion 52 softer than the first sealing resin portion 51. As a result, it is possible to suppress deterioration of the device characteristic of the power transistor 21 and the power diode 22 while suppressing a warp of the dielectric film 10.

Further, in this embodiment, since the frame member 40 is disposed on the first surface 10a of the dielectric film 10, it is possible to effectively suppress a warp of the dielectric film 10 by using the rigidity of the frame member 40 itself. Further, also in the case where the occupied areas of the circuit parts 20 and the electrode layer 30 differ between the first mounting area al and the second mounting area a2 as in this embodiment, it is possible to suppress a warp of the dielectric film 10 and maintain the high degree of flatness of the semiconductor module 100. As a result, it is possible to stably secure the mounting reliability on the external substrate.

Further, by forming the frame member 40 with a material having a high thermal conductivity, the heat radiation property of the semiconductor module 100 is improved, and deterioration of the device characteristics due to heat can be suppressed. Further, since the frame member 40 is formed to have the same shape and size as those of the dielectric film 10, the frame member 40 is exposed from the side surface of the semiconductor module 100, and it is possible to further improve the heat radiation characteristics.

For example, in the case where the semiconductor module 100 is prepared by singulating a collective substrate, a single grid-like member in which a plurality of openings (the first opening 41 and the second opening 42) are periodically formed in the plane can be used for the frame member 40. Then, by dicing the center of the grid of the grid-like member after forming the first sealing resin portion 51 and the second sealing resin portion 52, the semiconductor module 100 in which the frame-like member is exposed from four side surfaces can be prepared. Since the frame member is formed of a metal or ceramic and the thermal conductivity of the frame member is higher than that of the resin, the frame member can be used instead of a heat sink or heat radiation fin.

Then, since the mounting areas a1 and a2 are divided by the openings 41 and 42 of the frame member 40, it is possible to deposit a sealing resin with high precision without using a separate masking material. Further, also in the case where a resin material having high fluidity is used particularly as the second sealing resin portion 52 provided in the second mounting area a2, the resin material can be blocked without flowing out to another area by the frame member 40, which improves the workability.

### Second Embodiment

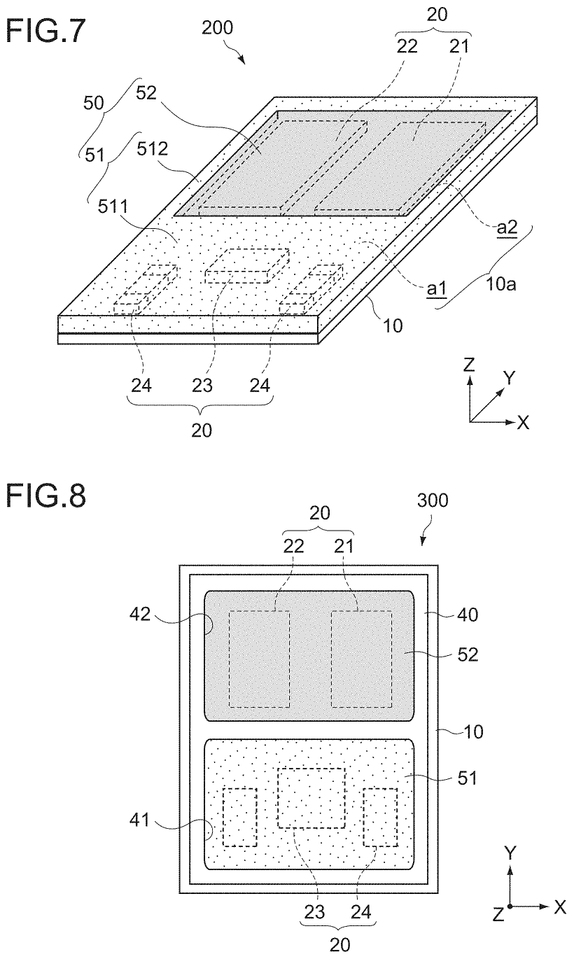

FIG. 7 is a schematic perspective view showing a configuration of a semiconductor module 200 according to a second embodiment of the present disclosure. Hereinafter, the configuration different from that in the first embodiment will be mainly described, and the same configuration as that of the first embodiment will be denoted by the same reference symbol, and description thereof will be omitted or simplified.

The semiconductor module 200 according to this embodiment is different from the semiconductor module 100 according to the first embodiment in that the semiconductor module 200 does not include the frame member 40. Specifically, the first sealing resin portion 51 according to this embodiment includes a first portion 511 and a second portion 512 having a frame shape. The first portion 511 covers the first mounting area a1. The second portion 512 divides the second mounting area a2, and is disposed around the second sealing resin portion 52.

In the semiconductor module 200 according to this embodiment, since the first sealing resin portion 51 is disposed not only on the first mounting area a1 but also around the second mounting area a2, it is possible to improve the rigidity of the peripheral portion of the dielectric film 10 by the first sealing resin portion 51. As a result, since a warp of the dielectric film 10 can be suppressed without using the frame member 40, it is possible to reduce the number of parts and number of assembling steps.

The method of forming the first sealing resin portion 51 is not particularly limited. For example, a screen printing method can be adopted. The second sealing resin portion 52 can be formed by, for example, a potting method after preparing the first sealing resin portion 51 on the dielectric film 10.

Although embodiments of the present disclosure have been described above, the present disclosure is not limited to the above-mentioned embodiments, and various modifications can be made.

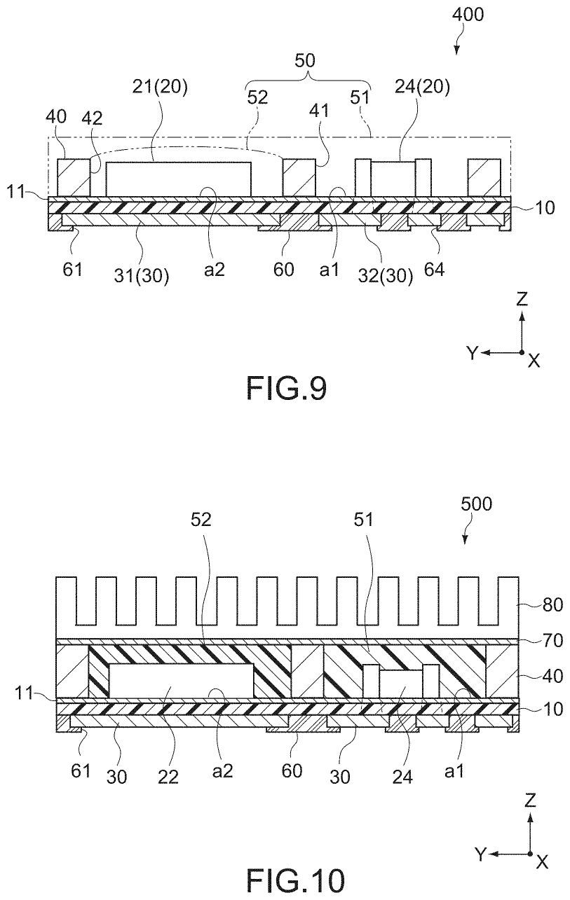

For example, although the case where the frame member 40 is formed to have the same shape and size as those of the dielectric film 10 has been described in the above-mentioned embodiments, the present disclosure is not limited thereto, and the peripheral portion of the dielectric film 10 may be formed to protrude outward from the four sides of the frame member 40 as in a semiconductor module 300 schematically shown in FIG. 8, for example. In this case, as in a semiconductor module 400 shown in FIG. 9, the first sealing resin portion 51 may be formed on the dielectric film 10 so as to cover the peripheral surface of the frame member 40 and the second sealing resin portion 52.

Further, as in a semiconductor module 500 shown in FIG. 10, a heat sink 80 may be mounted on the first sealing resin portion 51 and the second sealing resin portion 52 via an adhesive layer 70. As a result, it is possible to further improve the heat radiation property.

Further, in the case where an electrode having a wide width is provided on the opposite side of the dielectric film 10 to have a predetermined length as in the comb-shape electrodes (the first electrode portion 31 and the second electrode portion 32) shown in FIG. 5, the frame member 40 may be provided in the area overlapping with the electrode. In this case, the above-mentioned comb-shape electrodes are provided so as to extend over a half or more of the second mounting area a2 along the long side of the dielectric film 10, and are large electrodes having a width of 1 cm to 2 cm. The common electrode that makes the comb teeth common is a portion where the current of the transistor gathers, and the temperature thereof becomes high because of also heat generation of the transistor. Further, the common electrode has a certain width and length, a warp of the electrode itself occurs. Therefore, by providing the frame member 40 along the side of the dielectric film 10 at a position overlapping with the common electrode, it is possible to suppress a warp of the entire dielectric film 10 and a warp of the common electrodes. In particular, since a large number of vias (contacts with the power transistor) are opened at the comb teeth portion, a warp of the common electrode is suppressed, which improves the reliability of the power transistor via the vias. Further, since the frame member overlapping with the common electrode has an excellent thermal conductivity, the frame member is capable of storing heat generated in the electrode or collected in the electrode as a heat sink and dissipating heat from the four sides of the package to the outside as a heat radiation plate.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor module, comprising:
a dielectric film that has a first surface and a second surface opposed to the first surface, the first surface including a first mounting area and a second mounting area;
a plurality of circuit parts that includes a first circuit part and a second circuit part, the first circuit part being mounted on the first mounting area, the second circuit part being mounted on the second mounting area;
an electrode layer that is disposed on the second surface and includes a plurality of electrode portions to be electrically connected to the plurality of circuit parts; and
a sealing layer that includes a first sealing resin portion and a second sealing resin portion and seals the plurality of circuit parts, the first sealing resin portion covering the first mounting area, the second sealing resin portion being formed of a resin material softer than the first sealing resin portion and covering the second mounting area.

2. The semiconductor module according to claim 1, wherein
the first circuit part includes a passive device, and
the second circuit part includes a power semiconductor device.

3. The semiconductor module according to claim 1, further comprising
a frame member disposed on the first surface, wherein
the frame member includes a first opening and a second opening, the first opening dividing the first mounting area and housing the first sealing resin portion, and the second opening dividing the second mounting area and housing the second sealing resin portion.

4. The semiconductor module according to claim 3, wherein
the frame member is formed of a metal material or a ceramic material.

5. The semiconductor module according to claim 1, wherein
the first sealing resin portion includes a first portion and a second portion having a rectangular shape, the first portion covering the first mounting area, the second portion dividing the second mounting area and being disposed around the second sealing resin portion.

6. The semiconductor module according to claim 1, wherein
the first sealing resin portion is formed of an epoxy resin material, and
the second sealing resin portion is formed of a silicone resin material.

7. The semiconductor module according to claim 1, wherein
the dielectric film is formed of polyimide.

8. A semiconductor module, comprising:
a polyimide film having flexibility, the polyimide film having a first surface and a second surface opposed to the first surface;
a plurality of circuit parts provided on the first surface;
an electrode layer that is electrically connected to the plurality of circuit parts via vias provided in the polyimide film, and includes a plurality of electrode portions, the plurality of electrode portions being disposed on the second surface and having a thickness in a range of equivalent to the polyimide film to twice or twice or more the polyimide film;
a sealing layer that covers the first surface; and
a frame member that surrounds the sealing layer on the first surface and is exposed to side surfaces located at four sides of the dielectric film.

9. The semiconductor module according to claim 8, wherein
each of the plurality of electrode portions is provided around a side surface of the polyimide film to have a width of not less than 1 cm and not more than 2 cm, and
the frame member is provided at a position overlapping with the plurality of electrode portions.

10. The semiconductor module according to claim 8, wherein
the plurality of electrode portions includes a comb-shape electrode that is an electrode of a power transistor, the power transistor being one of the plurality of circuit parts.
